(19) United States
(12) Patent Application Publication
(10) Pub. No.: US 2017/0133540 A1
(43) Pub. Date: May 11, 2017

(54) P-Type Solar Cell and the Production Thereof

(71) Applicant: Karl W. BÖER, Naples, FL (US)

(72) Inventor: Karl W. BÖER, Naples, FL (US)

(21) Appl. No.: 14/971,579

(22) Filed: Dec. 16, 2015

(30) Foreign Application Priority Data
Nov. 11, 2015 (DE) 102015119489.9

(51) Int. Cl. H01L 31/073; H01L 31/18; H01L 31/0296

(52) U.S. Cl. CPC H01L 31/073; H01L 31/02963; H01L 31/1828; H01L 31/1864; H01L 31/1872

(57) ABSTRACT

A P-type solar cell comprises a layer stack with: a back electrode, a p-type semiconductor absorber layer disposed on the back electrode, a crystalline cadmium sulfide (CdS) layer disposed on the absorber layer, and a front electrode disposed on the side of the layer stack opposite the back electrode. The CdS layer has Cu-doping and a layer thickness between 50 and 300 Å. A method for producing a p-type solar cell comprises: providing a p-type photoactive semiconductor absorber layer, etching the surface of the absorber layer such that crystallographic unevenness and pinholes are reduced, depositing a CdS layer on the absorber layer, with a layer thickness between 50 and 200 Å, applying heat to at least the CdS layer to recrystallize the CdS layer, and optionally placing on the absorber layer a Cu-containing layer different from the CdS layer, either after etching or after the application of the CdS layer.

### CROSS REFERENCE TO RELATED APPLICATIONS

This application claims foreign priority under 35 U.S.C. §119(a)-(d) to Application No. DE 102015119489.9 filed on Nov. 11, 2015, the entire contents of which are hereby incorporated by reference.

### FIELD OF THE INVENTION

The invention relates to a p-type solar cell with a layer stack having a back electrode, a p-type semiconductor absorber layer disposed on the back electrode, a copper-doped cadmium sulfide (CdS) layer disposed on the absorber layer, a front electrode arranged on the side of the layer stack facing away from the back electrode, and a method for its production.

### BACKGROUND

Solar panels with high efficiency are always p-n cells which are able to separate the charge carriers and guide the separated charge carriers to the electrodes in order to generate a photo-voltage and a photo-current. Alternatively, an attempt was made to replace the p-n junction with a Schottky barrier. Such attempts have always failed because the solar cell had to be subjected to tempering in order to achieve a higher efficiency, which always caused a thin p-layer proximate to the Schottky Barrier to be doped n-type, thus effectively producing a p-n junction.

### SUMMARY

It is thus the object of the invention to avoid or to lessen the disadvantages of the prior art, and in particular to provide a p-type solar cell with improved electrical parameters.

This object is solved by a p-type solar cell and a method for producing such a p-type solar cell with the features of the independent claims. A first aspect of the invention therefore relates to a p-type solar cell with a layer stack which includes:
a back electrode,
a p-type semiconductor absorber layer arranged on the back electrode,
a copper-doped cadmium sulfide (CdS) layer arranged on the absorber layer,
a front electrode, which is arranged on the side of the layer stack facing away from the back electrode. According to the invention, the CdS layer is copper-doped and has a layer thickness in the range of 50 to 250 Å.

Surprisingly, it has been observed that the p-n junction in the solar cell according to the invention can be eliminated because a direct connection to the electrode has become possible due to the thin copper-doped CdS layer according to the invention, which has become p-type conducting in the interior due to a high-field domain. The domain has drift-conductivity and is space-charge-free—up to close proximity of the electrode—with a hole concentration in the order of 10¹⁰ cm⁻³, wherein the holes are generated by light and are able to tunnel freely into the domain without further losses.

The CdS layer according to the invention acts in an optimized manner as an electrochemical connection between the absorber layer and the front electrode. This has the particular advantage that the possible open circuit voltage V_{oc} is increased compared to cells of the prior art, since a high-field domain limits the electric field to far below about 100 kV/cm, i.e. to far less than the tunneling field strength which typically causes a leakage current through the diode that degrades the yield.

The density of charge carriers in these high-field domains is 1010 cm-3, resulting in a Debye length of more than 30 μm, which is thus significantly greater than the layer thickness of the CdS. The also means that the CdS acts as series resistance and must therefore be kept thin. A layer thickness is a compromise between a layer that is too thin and can easily have so-called pinholes and a layer that is too thick and has a loss of about 0.05 V in the open circuit voltage with each increase in thickness of 50 Å of CdS. At a layer thickness of 150 Å, the unavoidable losses are hence 0.15V at the theoretically achievable open circuit voltage. Nevertheless, for many p-type solar cells the open circuit voltage is up to 1 V greater than without the copper-doped CdS layer according to the invention.

Thus, the invention relates to a thin copper-doped CdS layer which is applied to any p-type solar cell and which connects the copper-doped CdS layer directly with an electrode that blocks electrons, and thus avoids a p-n junction that commonly causes losses for the open-circuit voltage and reduces the yield.

As an example, such a copper-doped CdS layer with a thickness of 200 Å can increase the open circuit voltage of a CdTe cell from 0.4 to 0.8 V. A thin layer may produce an additional increase of the open circuit voltage by 0.05V for each reduction in thickness by 50 Å.

The copper-doped CdS layer is p-type stabilized due to the limited replenishment of holes by the p-type solar cell, which provides the solar power. The p-type state in copper-doped CdS layer is generated by the high-field domain, which is attached to the p-type boundary to the solar cell and extends to proximate the front electrode, where the hole current is then conducted through tunneling. This prevents additional losses. The direct contact to the front electrode is made possible by the long Debye length which is much greater than the CdS layer thickness.

Typical efficiencies for thin layer solar modules are at most 18%. It can be expected that such efficiencies can be increased to more than about 22% when, in addition to CdTe cells with other types of absorbers, such as a-Si, or the various homologs to CIS [chalcopyrite (CuIn (Ga)S/Se)], cells are provided with such copper-doped thin CdS layers, thus preventing a loss-generating p-n junction.

The advantage of the p-type solar cell according to the invention is therefore in particular an increase in the open circuit voltage V_{oc} with an only slightly increased series resistance Rₛ. In the p-type solar cell according to the invention, the transition of charge carriers between the absorber and the electrode, in particular at the interfaces, are facilitated and recombination is reduced, because the classic p-n junction is avoided. It turned out that in particular the combination of the p-type copper-doped CdS layer and a reduced CdS layer thickness to a value below 250 Å, in particular less than 200 Å, more preferably to 150 Å, improves the parameters of the thin layer solar cells according to the invention.

The high-field domain discovered by Boer is a field structure which is oriented perpendicular to equidistant current lines. They occur when the conductivity of a material decreases more steeply than linear. For a further discussion in relation to high-field domains, reference is made to the feature article in the Annals of Physics 2015 (Ann. Phys. (Berlin) 527, No. 5-6, 378-395 (2015)) which is incorporated herein by reference.

The common thin layer materials such as CIS, a-Si and CdTe are used as absorber material.

The CdS layer is preferably formed as a crystalline single layer. Alternatively, the CdS layer has a multilayer structure, wherein the sum of the layer thicknesses of all CdS layers of the layer stack corresponds to the range of 50 to 250 Å according to the invention. CdS layer thicknesses below 50 Å increase the risk of defects within the layer transition, for example pinholes. To prevent pinholes in the layer and to keep the series resistance of the layer as small as possible (the open circuit voltage decreases by about 0.05V with each increase in the thickness of the CdS layer by 50 Å) the copper-doped CdS layer has a thickness of 50 to 250 Å, in particular 150 Å.

In a preferred embodiment of the invention, the CdS layer has a layer thickness in the range of 80 to 200 Å, in particular in the range of 100 to 180 Å, particularly preferred of 150 Å. These layer thicknesses of CdS layer showed an increasingly optimized relationship between reducing short circuits, for example caused by uncovered pinholes, and an increase in the electrical properties of the cell due to the influence of high-field domains.

In another preferred embodiment of the invention, the CdS layer has a proportion of a dopant in the range of 30-90 ppm, preferably in the range of 40 to 80 ppm, in particular 60 ppm. The doping is an essential factor affecting the p-type or n-type nature of the CdS layer, and cells with such doping exhibited the best parameters, in particular in connection with the CdS layer thickness. In a particularly preferred embodiment, the dopant includes elements of the transition group metals, in particular copper, silver or gold. Particularly advantageously, the dopant is copper. Doping, particularly with copper, should optimally be in the range of 60 ppm in order to facilitate dissolution of the high-field domains and the interface to the junction of the p-type emitter. However, the layer would still work according to the invention in a wide tolerance range between 30 and 100 ppm.

Another aspect of the invention is a method of manufacturing a p-type solar cell according to the invention. Here, the method includes at least the following steps in the listed order or in the reverse order. First, a p-type photoactive semiconductor absorber layer is provided. Thereafter, the surface of the absorber layer is etched to reduce crystallographic irregularities. The cadmium sulfide layer can then be applied more homogeneously and with less deep pinholes. After the application of cadmium sulfide (CdS) layer on the absorber layer with a layer thickness in the range of 50 to 250 Å, a recrystallization step with application of heat is carried out. Optionally, a Cu-containing CdS layer is applied, after etching on the absorber layer.

Additionally, a front electrode and a back electrode are each arranged on the layer stack. To this end, depending on whether it is a substrate or a superstrate structure, one starts with the front electrode, to which the CdS layer is connected, or with the back electrode facing the absorber layer.

To prevent defects in the thin copper-doped CdS layer, the backing layer of the emitter is subjected to a shallow etch according to the invention to smooth the surface, in particular to reduce pinholes, thus making the onset of the application of the CdS layer more homogeneous.

In a preferred embodiment, etching is performed with an etch solution composed of hydrochloric acid and a solvent, in particular glycerol. It is important that the acid is not too highly concentrated and too aggressive, since this would enlarge existing pinholes and produce an undesirable rough surface.

The CdS layer can be applied with one of the customary methods, such as by vapor deposition, spraying, electro-chemical, sputtering or the like, but preferably by a method that does not damage the surface of the emitter, i.e. by evaporation in vacuum at a slightly elevated temperature commensurate with the compatibility of the emitter. Advantageously, the CdS layer is therefore applied by vapor deposition of a CdS-phase on the absorber layer.

Furthermore, the CdS layer is preferably doped simultaneously with the application of the CdS layer, and/or by diffusion of the dopant from a layer adjoining the CdS layer, in particular the absorber layer or a flux agent. The beneficial effect of doping has already been described above. Preferably, CdCl₂ is used as a flux agent.

It is particularly advantageous to subject the entire solar cell to a recrystallization after the vapor deposition is completed, which is preferably initiated by way of a thin CdCl₂ layer (the flux agent). This flux agent normally contains enough copper impurities sufficient for doping the CdS layer.

The construction of the electrode connected to the CdS depends on the desired type of the solar cell (front wall or rear wall cell) and can be either transparent or metallic opaque and may block electrons. However, this is irrelevant for the transition of the holes which in any event takes place by tunneling.

The absorber layer is applied in a conventional manner, i.e. for CdTe absorbers for example by vapor deposition, and for CIS absorbers for example by sputtering.

After connection of the absorber and the CdS layer, preferably prior to the preparation of the back contact, the solar cells are subjected to heat treatment, preferably in a chlorine-containing atmosphere. The performance (VOC, JSC, FF) of the solar cell is improved even more with this activation.

In a particularly preferred embodiment of the invention, heat is applied at a temperature in the range of 300 to 500° C., in particular in the range of 300 to 400° C., more preferably at 350° C. The previously deposited CdS recrystallizes in these temperature ranges. The associated reduction of macroscopic grain boundaries reduces recombination effects and in particular improves the fill factor of the cell.

Particularly advantageously, heat is applied for a duration in the range of 0.5 to 4 hours, particularly in range of 0.5 to 2 hours, preferably 1 hour. Advantageously, this process step is performed using CdCl2 as a flux agent, which is then applied, for example, to the layer stack. Alternatively, heat is applied in a CdCl2 atmosphere, for example in an annealing furnace.

Alternatively, any other n-type absorber material (AB), in particular from the group of chalcogenides, can be used instead of CdS in the p-type solar cell according to the invention. This n-type absorber material is doped, as described above by way of example for CdS, with one of the aforedescribed dopants, with the effect that a high-field domain with the advantages described above is formed in the absorber material AB.

As described with reference to the example of CdS, shallow etching is performed in the production of p-type solar cells with n-type absorber materials (AB), in particular from the group of chalcogenides, for example in the manner described above.

The embodiments of the p-type solar cell as well as their manufacturing methods are also applicable to the other n-type absorber materials (AB), in particular from the group of chalcogenides.

Preferably, a dopant known as good hole trap is selected for doping of the n-type absorber material. These include, in particular, so-called double-Coulomb traps. Particularly preferred are therefore elements from the group of transition metals, such as silver, gold and/or copper. The dopant is enriched in the n-type absorber depending on the specific saturation of the dopant in the n-type absorber for the aforedescribed heat treatment, so that at least approximately a uniform distribution is achieved, at least in a thickness range of 100 Å.

Further preferred embodiments of the invention will be apparent from the other features recited in the dependent claims.

The various embodiments of the invention mentioned in this application can advantageously be combined with each other, unless otherwise noted for individual cases.

### BRIEF DESCRIPTION OF THE DRAWINGS

The invention will now be described with reference to exemplary embodiments illustrated in the drawings, which show in:

FIG. 1 a schematic diagram of a layer stack in a preferred embodiment of the invention, and

FIG. 2 a diagram of the band structure at the interface between the absorber layer and the p-doped CdS layer by forming a high-field domain in a preferred embodiment of the invention.

### DETAILED DESCRIPTION

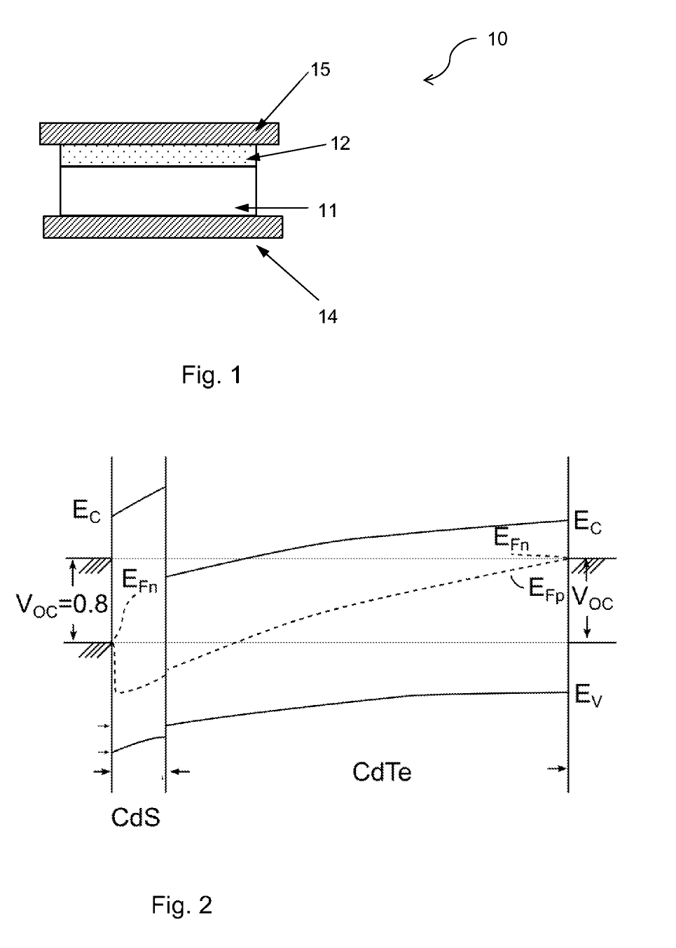

FIG. 1 shows a schematic diagram of a layer stack 10 in a preferred embodiment of the invention. Shown is the schematic structure of the layer sequence in an exemplary rudimentary form.

The layer stack 10 includes a back electrode 14, on which an electrically conductive absorber layer 11 is arranged. The absorber layer 11 includes a semiconductor material exhibiting an internal photo effect, such as CdTe. Alternatively, the absorber material may include a semiconductor material from the group of CIS absorbers (copper indium (gallium)—sulfide (selenide)).

A copper-doped CdS layer 12 is disposed on the side of the absorber layer 11 facing away from the back electrode 14. The CdS layer 12 has a thickness in the range of 80 to 200 Å, preferably in the range of 100 to 180 Å, in particular 150 Å. The CdS layer 12 is also p-doped and is preferably doped with copper. The dopant concentration is in the range of 30 - 90 ppm, preferably in the range of 40 to 80 ppm, in particular 60 ppm. The concentration is distributed within the Cd S-layer 12 as uniformly as possible in relation to a plane parallel to the layers boundaries. The concentration may also be uniformly distributed In relation to the layer thickness of the CdS layer 12, or may in a preferred embodiment have a gradient, in which case the concentration decreases starting from the interface between the absorber layer 11 and the CdS layer 12.

The CdS layer 12 is in a crystalline state, i.e. is preferably not amorphous, preferably in the form of microscopic crystallites or macroscopic crystallites.

A high-field domain is formed within the CdS layer 12. Depending on the layer thickness, the doping level and the degree of crystallization of the CdS layer, the high-field domain extends through and beyond the layer thickness of the CdS.

The layer stack 10 is part of a photovoltaic thin layer cell which is generally encapsulated and connected (not shown). The function results in particular from the internal photoelectric effect of the absorber material. When light is incident, a photocurrent is generated within the absorber layer 11 due to the separation by the light excitation of charge carrier pairs that are generated in the space charge region, i.e. in the p/n-junction. The excited charge carriers are carried away by the electrodes that are electrically conductively connected to the absorber material. The inventive design of the cell, in particular the optimization of the transition between the absorber layer 11 and CdS layer 12, enables utilization of the largest possible proportion of the generated charge carriers, i.e. the theoretical efficiency of the cell is to the most part achieved. It turned out that the effect is to a large part due to the p-type nature of the CdS layer 12. This layer has a space-charge-free high-field domain, with a density of free charge carriers (holes) of up to 10¹⁰ cm⁻³.

Therefore, the cell according to the invention has a high open-circuit voltage V_{oc}, with an only slightly increased series resistance.

Such cells can be produced with the method according to the invention.

### Preferred Exemplary Embodiment:

In a particularly preferred exemplary embodiment, a p-type solar cell according to the invention has a CdTe absorber layer with a layer thickness in the range of 1.5 to 2.5 μm preferably 2 μm. A Cu-doped CdS layer is disposed on the surface the absorber layer facing a front electrode. The dopant concentration in the CdS layer is in a range from 30 to 90 ppm, especially with 60 ppm Cu. The CdS layer has a layer thickness of 130 to 200 Å, preferably 150 Å.

A band structure as shown in FIG. 2 could be determined for a p-type solar cell according to the preferred exemplary embodiment. Shown are the conduction band and the valence band of the cell in the region absorber layer/CdS layer.

The employed CdTe absorber material has at a temperature of 0K a band gap of 1.45 eV, a photocurrent with a short-circuit current density j_{SC} of 26 mA/cm² and an electric field of 100 kV/cm. A hole density of p(CdS)=5.1·10¹⁰ cm⁻³ was determined, resulting in a band discontinuity between valence band and conduction band E_{Fp}-Eᵥ=0.48 eV in CdS. The hole density for the absorber layer is diffusion-limited in the region of the interface. In the described preferred embodiment, the hole density p(CdTe) is 1.25·10¹⁰ cm⁻³ and the band discontinuity at the interface CdTe/CdS is E_{Fp}-Eᵥ=0.54 eV. Based on these values, a Debye length L_{D} of 15,000 μm was determined. This is based on the following calculation of the Debye length

$$L = {[ \frac{ɛ T {10}^{15}}{( 10 \times 300 p )} ]}^{1 / 2}$$

This means in turn that the field in the thin layer cell according to the invention with the very small CdS layer thickness is constant within the CdS layer over the entire layer thickness. The discontinuity to the Fermi level of the metal is so small that the free charge carriers p can tunnel through the junction without experiencing a significant loss in the current.

### LIST OF REFERENCE NUMBERS

10 Layer stack
11 Absorber layer
12 CdS layer with high-field domain
14 Back electrode
15 Front electrode

What is claimed is:

1. P-type solar cell comprising a layer stack (10) with:
a back electrode (14),
a p-type semiconductor absorber layer (11) disposed on the back electrode (14),
a crystalline cadmium sulfide (CdS) layer (12) disposed on the absorber layer (11),
a front electrode (15) disposed on the side of the layer stack (10) opposite of the back electrode (14),
characterized in that the CdS layer (12) has Cu-doping and a layer thickness in the range of 50 to 300 Å.

2. P-type solar cell according to claim 1, characterized in that the CdS layer (12) has a layer thickness in the range of 80 to 200 Å, in particular in the range of 100 to 180 Å, preferably 150 Å.

3. P-type solar cell according to claim 1, characterized in that the CdS layer (12) has a proportion of 30-80 ppm, preferably in the range of 40 to 80 ppm, in particular 60 ppm, of a dopant.

4. P-type solar cell according to claim 1, characterized in that the dopant of the CdS layer (12) is copper.

5. Method for producing a p-type solar cell, comprising the following steps in the specified order, or in the reverse order:
providing a p-type photoactive semiconductor absorber layer (11),
etching the surface of the absorber layer (11) such that crystallographic unevenness and pinholes are reduced,
depositing a CdS layer (12) on the absorber layer (11), with a layer thickness in the range of 50 to 200 Å,
applying heat to at least the CdS layer to recrystallize the CdS layer (12), as well as
optionally placing on the absorber layer (11) a Cu-containing layer different from the CdS layer, either after etching or after the application of the CdS layer (12).

6. Method according to claim 5, characterized in that the CdS layer (12) is applied on the absorber layer (11) by vapor deposition of a CdS phase.

7. Method according to claim 5, characterized in that etching is performed by using an etching solution comprising hydrochloric acid and a solvent, in particular glycerol.

8. Method according to claim 6, characterized in that heat is applied at a temperature of at least 350° C., in particular in the range of 350 to 500° C., preferably in the range of 350 to 450° C.

9. Method according to claim 6, characterized in that heat is applied for a duration in the range of 0.5 to 4 h, especially in the range of 0.5 to 2 h.
